(19) United States
(12) Patent Application Publication
(10) Pub. No.: US 2007/0090885 A1
(43) Pub. Date: Apr. 26, 2007

(54) CHARGE PUMP CIRCUIT AND PHASE-LOCKED LOOP CIRCUIT

(75) Inventor: Yukio OKAZAKI, Kadoma-shi, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/548,498

(22) Filed: Oct. 11, 2006

(30) Foreign Application Priority Data
Oct. 20, 2005 (JP) JP2005-305502

(51) Int. Cl. H03L 7/00

(52) U.S. Cl. 331/16

(57) ABSTRACT

A first current source for sinking electrical current, a first differential circuit for switching the electrical current of the first current source according to an input signal, a second current source for sourcing electrical current, a second differential circuit for switching the electrical current of the second current source according to an input signal, and at least one amplitude limiter/attenuator circuit that reduces the input signal to a desired voltage amplitude and supplies it as a control signal that switches the first and second differential circuits are provided, respective outputs of the first and second differential circuits being combined as output. Disturbances of the output current that are consequent upon driving the switching elements and result from channel charges below gate electrodes and parasitic source and drain capacitances are suppressed.

### BACKGROUND OF THE INVENTION

1. Field of the Invention

The present invention relates to a charge pump circuit and a phase-locked loop circuit employing the same.

2. Description of Related Art

A general configuration of a phase-locked loop (called “PLL” in the following) circuit is shown in FIG. 10. In this circuit, a reference signal outputted by a base-signal generator 101 and an output signal of a frequency divider 106 are inputted to a phase comparator 102. The frequency divider 106 divides an oscillation frequency of a voltage-controlled oscillator 105 by N. The phase comparator 102 compares the phases of the reference signal and of the signal resulting from the 1/N division of the oscillation frequency of the voltage-controlled oscillator 105, and controls the output of a charge pump 103 such that the phase difference becomes zero. The output of the charge pump 103 is supplied to the voltage-controlled oscillator 105 via a low-pass filter (LPF) 104, constructing a feedback loop. Hence, an N-multiple of the oscillation frequency of the reference signal is obtained as oscillation output.

When feeding back the phase difference signal outputted by the phase comparator 102 to the voltage-controlled oscillator 105, the control voltage is generated by the charge pump 103, with the characteristics of the feedback loop being determined by the low-pass filter (LPF) 104. The behavior demanded of the charge pump 103 is to output an output pulse current that is faithful to the output of the phase comparator 102. Otherwise, a consistently flawed phase comparison result would be outputted to the LPF 104, leading to the occurrence of jitter at the output of the voltage-controlled oscillator 105.

The LPF 104 is increasingly implemented on an IC because of miniaturization of machinery and tools. However, as the LPF 104 is composed of a resistor and a capacitance element, it is necessary to reduce τ the current of charge pump 103 in order to reduce the capacitance to an extent that can be realized on the IC.

Accordingly, a preferably simple configuration of the charge pump 103 is desired that enables making the current output small (a few μA to a few tens of μA), while delivering a current output faithful to the output of the phase comparator 102.

A configuration of a typical charge pump is shown in FIG. 11. In order to output CPout, the circuit controls, according to an input signal, electrical currents supplied by a current source MP90 and a current source MN90, by means of switching transistors MP91, MP92 (p-type MOS transistors) and switching transistors MN91, MN92 (n-type MOS transistors). The input signal is a phase comparator output that is a digital output with a high level (substantially power-supply voltage) and a low level (substantially ground voltage), and is applied as Up, UpB, Down, DownB to the gates of the switching transistors MP91, MP92, MN91, MN92.

By the way, the channel electrical charge occurring below the gate of an n-type MOS transistor is given by the following expression.
Q=W·L·Cox(VGS−Vth) (1)

Here, W and L respectively are the gate width and gate length of the transistor, Cox is the gate capacitance per unit area, VGS is the gate-to-source voltage of the transistor, and Vth is the threshold voltage of the transistor.

Assuming that, in the charge pump of FIG. 11, the gate voltage of the switching transistor MN91 has risen to the power-supply voltage, the electrical charge Q from the above Expression (1) is induced. As long as this charge Q is not completely sunken by the current source MN90, it appears as electrical current at the drain and source terminals of the switching transistor MN91. That is to say, electrical currents besides the current sunken by current source MN90 occur and cause disturbances in the output current. For smaller electrical current sunken by the current source MN90, the ratio of such disturbance becomes larger, causing inaccuracies in the output current.

Moreover, the gates of the switching transistors MN91 and MN92 are supplied with the digital output signals Down, DownB of the phase comparator. Because of a digital signal, the amplitude changes steeply by a large amount, so that the source voltage of the switching transistors MN91 and MN92 fluctuates transitionally. Because the source terminals of the switching transistors MN91 and MN92 are connected to the drain of the current source MN90, the drain-terminal voltage of the current source MN90 varies as well. Consequently during variations of Down and DownB the parasitic capacitance of the drain of the current source MN90 is charged or discharged, which also causes inaccuracies in the output current.

While the above explained actions on the side that sinks the electrical current, the same can be said about the side that sources an electrical current. That is, when directly applying a signal with a large amplitude such as a digital signal to the switching transistors at the charge pump output, inaccuracies in the output current result.

A charge pump circuit according to JP 2002-330067A, which was constructed in order to improve such a situation, is shown in FIG. 12. This charge pump circuit has constant-current circuits 21, 23, p-type MOS transistors 22a, 22b, n-type MOS transistors 24a, 24b, switch circuits 25, 27, and voltage-generating circuits 26, 28. The circuit composed of the constant-current circuits 21, 23, the p-type MOS transistors 22a, 22b, and the n-type MOS transistors 24a, 24b has the same function as the circuit shown in FIG. 11.

The constant-current circuit 21 has p-type MOS transistors 21a, 21b constituting a current-mirror circuit, and a constant-current circuit 21c. The constant-current circuit 23 has n-type MOS transistors 23a, 23b constituting a current-mirror circuit, and a constant-current circuit 23c.

The voltage-generating circuit 26 has a p-type MOS transistor 26a, and a constant-current circuit 26b connected between an output line N26 and a ground line. The voltage-generating circuit 28 has an n-type MOS transistor 28a, and a constant-current circuit 28b connected between an output line N28 and a power-supply line.

The switch circuit 25 has CMOS switches 25b, 25d, a p-type MOS transistor 25a, and a p-type MOS transistor 25c. A signal Up is inputted to the gates of the p-type MOS transistor 25a, the n-type MOS transistor of CMOS switch 25b, and the p-type MOS transistor of CMOS switch 25d. A signal/Up being an inverse signal to the signal Up is inputted to the gates of the p-type MOS transistor 25c, the p-type MOS transistor of CMOS switch 25b, and the n-type MOS transistor of CMOS switch 25d.

When the signal Up is high-level, in this switch circuit 25 the CMOS switch 25b and the p-type MOS transistor 25c assume a conductive state, while the CMOS switch 25d and the p-type MOS transistor 25a assume a non-conductive state. By this, the gate of the p-type MOS transistor 22a is connected to the power-supply line, and the gate of p-type MOS transistor 22b is connected to the output line N26 of the voltage-generating circuit 26. Also, when the signal Up is low-level, the gate of the p-type MOS transistor 22a is connected to the output line N26, and the gate of the p-type MOS transistor 22b is connected to the power-supply line.

The switch circuit 27 has CMOS switches 27b, 27d, an n-type MOS transistor 27a, and an n-type MOS transistor 27c. When the signal DN is high-level, the gate of the n-type MOS transistor 24a is connected to the output line N28 of the voltage-generating circuit 28, and the gate of the n-type MOS transistor 24b is connected to the ground line. Also, when the signal DN is low-level, the gate of the n-type MOS transistor 24a is connected to the ground line, and the gate of the n-type MOS transistor 24b is connected to the output line N28.

The operation of this charge-pump circuit is as follows. When the signal DN is high-level, the gate of the n-type MOS transistor 24a is connected via the CMOS switch 27b to the output line N28 of the voltage-generating circuit 28, and the gate of the n-type MOS transistor 24b is connected via the n-type MOS transistor 27c to the ground line. Hence, the n-type MOS transistor 24a assumes a conductive state, while the n-type MOS transistor 24b assumes a non-conductive state. The electrical current of the constant-current circuit 23 flows from the current input/output terminal LPF via the n-type MOS transistor 24a into the constant-current circuit 23, without flowing through the n-type MOS transistor 24b.

When the signal Up is low-level, the gate of the n-type MOS transistor 24a is connected via the n-type MOS transistor 27a to the ground line, and the gate of the n-type MOS transistor 24b is connected via the CMOS switch 27d to the output line N28 of the voltage-generating circuit 28. Hence, the n-type MOS transistor 24a assumes a non-conductive state, while the n-type MOS transistor 24b assumes a conductive state. The electrical current of the constant-current circuit 23 flows from the power-supply line VDD via the n-type MOS transistor 24b into the constant-current circuit 23, without flowing through the n-type MOS transistor 24a. In this way, the electrical current of the constant-current circuit 23 flows through either the n-type MOS transistor 24a or the n-type MOS transistor 24b, depending on the level of the signal DN.

Therefore, the voltage at the parasitic capacitance occurring in parallel to the constant-current circuit 23 becomes substantially uniform, not depending on the level of the signal DN, such that charging and discharging of electrical charge for the parasitic capacitance is suppressed. The case of the signal Up is identical.

In this example, while disturbances to the output current due to charging and discharging of parasitic capacitances can be remedied, a great number of switching transistors and capacitance elements for smoothing are required, which when implemented on an integrated circuit occupy a large area, becoming a cost-raising factor. Here, a simpler circuit is desired.

Disturbances, such as described above, to the output current of a charge pump, which, when driving digitally with a large amplitude the gate of a transistor that controls the output current of the charge pump, arise due to the parasitic source and drain capacitances of the transistor and the channel charge below the gate electrode, are significant when a low charge-pump current is required. As a result, a charge-pump output current faithful to the output of the phase comparator becomes difficult to obtain, and undesirable effects such as increased jitter arise.

### SUMMARY OF THE INVENTION

It is an object to the present invention to provide a charge pump circuit that by a simple configuration is able to remedy disturbances to the output current at switching time, which, when driving digitally with a large amplitude the gate of a transistor that controls the output current of the charge pump, arise due to the parasitic source and drain capacitances of the transistor and the channel charge below the gate electrode.

A charge pump circuit of a fundamental configuration according to the present invention includes: a first current source for sinking electrical current; a first differential circuit for switching the electrical current of the first current source according to an input signal; a second current source for sourcing electrical current; a second differential circuit for switching the electrical current of the second current source according to an input signal; and at least one amplitude limiter/attenuator circuit that reduces the input signal to a desired voltage amplitude and supplies it as a control signal that switches the first and second differential circuits. Respective outputs of the first and second differential circuits are combined as output of the charge pump circuit.

### BRIEF DESCRIPTION OF THE DRAWINGS

FIG. 1 is a diagram showing a fundamental configuration of a charge pump according to an embodiment of the present invention,

FIG. 2 is a circuit diagram showing a configuration of a charge pump in a first embodiment of the present invention,

FIG. 3A is a circuit diagram showing a configuration of a variation example of the charge pump of FIG. 2,

FIG. 3B is a circuit diagram showing a configuration of another variation example of the charge pump of FIG. 2,

FIG. 4 is a circuit diagram showing a configuration of a charge pump in a second embodiment of the present invention,

FIG. 5A is a circuit diagram showing a configuration of a variation example of the charge pump of FIG. 4,

FIG. 5B is a circuit diagram showing a configuration of another variation example of the charge pump of FIG. 4,

FIG. 6 is a circuit diagram showing a configuration of a charge pump in a third embodiment of the present invention,

FIG. 7A is a circuit diagram showing a configuration of a variation example of the charge pump of FIG. 6,

FIG. 7B is a circuit diagram showing a configuration of another variation example of the charge pump of FIG. 6,

FIG. 8 is a diagram showing an output current wave form of the charge pump of FIG. 2,

FIG. 9 is a diagram showing an output current wave form of the charge pump of FIG. 11,

FIG. 10 is a block diagram showing a configuration of a typical PLL circuit,

FIG. 11 is a circuit diagram showing a configuration of a conventional charge pump, and

FIG. 12 is a circuit diagram showing a configuration of another conventional charge pump.

### DETAILED DESCRIPTION OF THE INVENTION

A charge-pump circuit of a fundamental configuration according to the present invention includes; a first current source for sinking an electrical current; a first differential circuit for switching the electrical current of the first current source depending on an input signal; a second current source for sourcing an electrical current; a second differential circuit for switching the electrical current of the second current source depending on the input signal; and at least one amplitude limiter/attenuator circuit. The amplitude limiter/attenuator circuit reduces the input signal to a desired voltage amplitude to supply it as a control signal for switching the first and second differential circuits. The outputs of the first and second differential circuits are combined as output.

According to this configuration, disturbances to the output current during switching that arise from parasitic transistor capacitances and channel charges can be remedied with a simple configuration. This is particularly desirable if the output current is a small current of a few tens of μA.

In the above fundamental configuration, the amplitude limiter/attenuator circuit connected to the first differential circuit can include: a series circuit having a first switching element supplied with the input signal as control signal, a first resistance element, and a second resistance element, which are connected in series, the first switching element side being connected to a power-supply voltage and the second resistance element side being grounded; and a series circuit having a second switching element supplied with the input signal as control signal, a third resistance element, and a fourth resistance element, which are connected in series, the second switching element side being connected to a power-supply voltage and the fourth resistance element side being grounded. Output signals from the node between the first resistance element and the second resistance element and the node between the third resistance element and the fourth resistance element are inputted into the first differential circuit.

On the other hand, the amplitude limiter/attenuator circuit connected to the second differential circuit can include: a series circuit having a third switching element supplied with the input signal as control signal, a fifth resistance element, and a sixth resistance element, which are connected in series, the third switching element side being connected to a ground potential and the sixth resistance element side being connected to the power-supply voltage; and a series circuit having a fourth switching element supplied with the input signal as control signal, a seventh resistance element, and an eighth resistance element, which are connected in series, the fourth switching element side being connected to the ground potential and the eighth resistance element side being connected to the power-supply voltage. Output signals from the node between the fifth resistance element and the sixth resistance element and the node between the seventh resistance element and the eighth resistance element are inputted into the second differential circuit.

This configuration can include a first diode-connected transistor inserted between the ground potential and the second resistance element together with the fourth resistance element, and a second diode-connected transistor inserted between the power-supply voltage and the sixth resistance element together with the eighth resistance element.

Also, the configuration can include a ninth resistance element inserted between the ground potential and the second resistance element together with the fourth resistance element, and a tenth resistance element inserted between the power-supply voltage and the sixth resistance element together with the eighth resistance element.

Also, in the above fundamental configuration, the amplitude limiter/attenuator circuit connected to the first differential circuit can include: an 11th resistance element connected at one end to a power-supply voltage; a series circuit having a first switching element supplied with the input signal as control signal and a 12th resistance element, which are connected in series, the first switching element side being connected to a ground potential and the 12th resistance element side being connected to the other end of the 11th resistance element; and a series circuit having a second switching element supplied with the input signal as control signal and a 13th resistance element, which are connected in series, the second switching element side being connected to the ground potential and the 13th resistance element side being connected to the other end of the 11th resistance element. Output signals from the node between the first switching element and the 12th resistance element and the node between the second switching element and the 13th resistance element are inputted into the first differential circuit.

On the other hand, the amplitude limiter/attenuator circuit connected to the second differential circuit can include: a 14th resistance element connected at one end to the ground potential; a series circuit having a third switching element supplied with the input signal as control signal and a 15th resistance element, which are connected in series, the third switching element side being connected to the power-supply voltage and the 15th resistance element side being connected to the other end of the 14th resistance element; and a series circuit having a fourth switching element supplied with the input signal as control signal and a 16th resistance element, which are connected in series, the fourth switching element side being connected to the power-supply voltage and the 16th resistance element side being connected to the other end of the 14th resistance element. Output signals from the node between the third switching element and the 15th resistance element and the node between the fourth switching element and the 16th resistance element are inputted into the second differential circuit.

This configuration can include a third diode-connected transistor inserted between the 11th resistance element and the 12th resistance element together with the 13th resistance element, and a fourth diode-connected transistor inserted between the 14th resistance element and the 15th resistance element together with the 16th resistance element.

Also, the third transistor can include a plurality of diode-connected transistors connected in series, and the fourth transistor can include a plurality of diode-connected transistors connected in series.

Also in the above fundamental configuration, the amplitude limiter/attenuator circuit connected to the first differential circuit can include; a third current source connected at one end to a power-supply voltage; a series circuit having a first switching element supplied with the input signal as control signal and a 17th resistance element, which are connected in series, the first switching element side being connected to the other end of the third current source and the 17th resistance element side being grounded; and a series circuit having a second switching element supplied with the input signal as control signal and an 18th resistance element, which are connected in series, the second switching element side being connected to the other end of the third current source and the 18th resistance element side being grounded. Output signals from the node between the first switching element and the 17th resistance element and the node between the second switching element and the 18th resistance element are inputted into the first differential circuit.

On the other hand, the amplitude limiter/attenuator circuit connected to the second differential circuit can include: a fourth current source grounded at one end; a series circuit having a third switching element supplied with the input signal as control signal and a 19th resistance element, which are connected in series, the third switching element side being connected to the other end of the fourth current source and the 19th resistance element side being connected to the power-supply voltage; and a series circuit having a fourth switching element supplied with the input signal as control signal and a 20th resistance element, which are connected in series, the fourth switching element side being connected to the other end of the fourth current source and the 20th resistance element side being connected to the power-supply voltage. Output signals from the node between the third switching element and the 19th resistance element and the node between the fourth switching element and the 20th resistance element are inputted into the second differential circuit.

Also, the configuration can include a fifth diode-connected transistor inserted between the ground potential and the 17th resistance element together with the 18th resistance element, and a sixth diode-connected transistor inserted between the power-supply voltage and the 19th resistance element together with the 20th resistance element.

Also, the configuration can include a 21st resistance element inserted between the ground potential and the 17th resistance element together with the 18th resistance element, and a 22nd resistance element inserted between the power-supply voltage and the 19th resistance element together with the 20th resistance element.

A phase-synchronized loop circuit of the present invention can include a voltage-controlled oscillator, a frequency divider that divides a frequency of an output signal of the voltage-controlled oscillator, a phase comparator that compares the phases of a reference signal and an output signal of the frequency divider, a charge pump controlled by an output signal of the phase comparator, and a low-pass filter supplied with the output of the charge pump, where within a configuration of the voltage-controlled oscillator being controlled by the output of the low-pass filter. As the charge-pump, a charge-pump circuit of any one of the above-mentioned configurations can be used, and the output signal of the phase comparator is inputted as an input signal into the amplitude limiter/attenuator circuit.

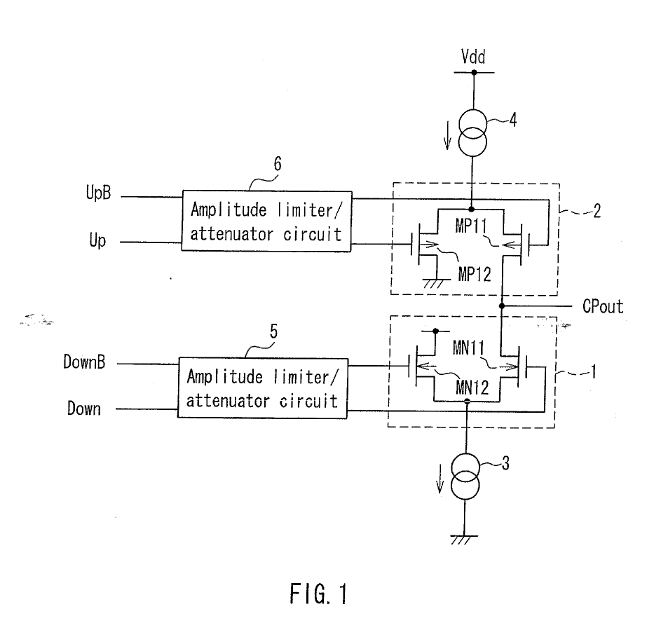

In the following, embodiments of the present invention will be explained with reference to the drawings. FIG. 1 shows a basic configuration of a charge pump according to an embodiment of the present invention.

In this charge-pump, differential switching circuits 1, 2 and current sources 3, 4 constitute an electrical-current supply circuit. In the respective differential switching circuits 1, 2, n-type MOS transistors MN11, MN12, and p-type MOS transistors MP11, MP12 are used in differential configuration. The current sources 3, 4 are connected respectively to the differential switching circuits 1, 2, an output signal CPout being generated by switching their electrical current.

Respective digital signals Up, UpB, Down, DownB from a phase comparator (not shown) are supplied via amplitude limiting or attenuating circuits (amplitude limiter/attenuator circuits) 5, 6 to the gates of the transistors MN11, M12 and MP11, MP12. Up, UpB are signals instructing to source electrical current, UpB being the inverse signal to Up. Down, DownB are signals instructing to sink electrical current, DownB being the inverse signal to Down.

The respective logic amplitudes at the transistor gates are kept small by the amplitude limiter/attenuator circuits 5, 6, thereby remedying disturbances to the output current caused by parasitic capacitances and channel charges. As will be explained below, the amplitude limiter/attenuator circuits 5, 6 include switching transistors and resistors switched by the digital signals Up, UpB, Down, DownB from the phase comparator, and can be provided as simple circuits.

In the following, charge pumps in various embodiments of the present invention will be explained that are concrete configurations based on the fundamental configuration of FIG. 1.

### FIRST EMBODIMENT

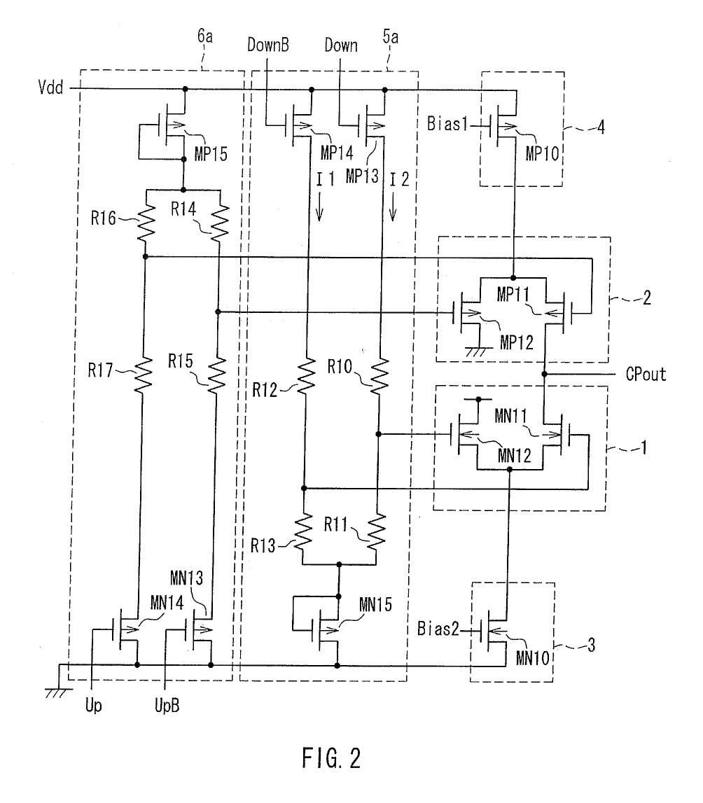

FIG. 2 shows a configuration of a charge pump in a first embodiment of the present invention. The differential switching circuits 1, 2 and the current sources 3, 4, which function as the electrical-current supply circuit of this charge pump, are composed of n-type MOS transistors MN10, MN11, MN12 and p-type MOS transistors MP10, MP11, MP12.

MN10 and MP10, which respectively constitute the current sources 3, 4, operate as current sources due to Bias1, Bias2 being applied to the respective gates. MN11, MN12 and MP11, MP12, which respectively constitute the differential switching circuits 1, 2, perform switching of the electrical current of the current sources 3, 4, by means of a switching signal being applied to their gates in the following way.

An attenuator circuit 5a includes transistors MP13, MP14, MN15, resistance elements R10, R11, R12, R13, and attenuates the signal voltage applied to the gates of MN11, MN12, which constitute the differential switching circuit 1.

In the same way, an attenuator circuit 6a includes transistors MN13, MN14, MP15, resistance elements R14, R15, R16, R17, and attenuates the signal voltage applied to the gates of MP11, MP12, which constitute the differential switching circuit 2.

The operation of the attenuator circuit 5a is explained as follows. Assuming that Down has become high-level (substantially power-supply voltage), and DownB has become low-level (substantially ground voltage), MP13 blocks, while MP14 is conductive. If at this time denoting the on-resistance of MP14 as Rds and the gate-to-source voltage at on-time of MN15 as VGS15, the current passing through MP14, R12, R13 is given by Expression (2).

$$I 1 = \frac{Vdd - VGS 15}{Rds + R 12 + R 13} \qquad ( 2 )$$

The gate voltage of MN11 assumes a value given by Expression (3).

$$\begin{matrix}VGS 15 + R 13 \times I 1 = VGS 15 + \frac{R 1 \; 3}{Rds + R 12 + R 13} \times \\ ( Vdd - VGS 15 )\end{matrix} \qquad ( 3 )$$

The gate voltage of MN12 becomes VGS15 since no current is passing through R10, R11. MN11 becomes conductive, sinking electrical current from CPout, because the gate voltage of MN11 is higher than the gate voltage of MN12.

Assuming next that Down, DownB have each been reversed, MP14 blocks while MP13 is conductive. If denoting the on-resistance of MP13 as Rds, an electrical current given by Expression (4) passes through MP13, R10, R11.

$$I 2 = \frac{Vdd - VGS 15}{Rds + R 10 + R 11} \qquad ( 4 )$$

The gate voltage of MN12 assumes a value given by Expression (5).

$$\begin{matrix}VGS 15 + R 11 \times I 2 = VGS 15 + \frac{R 11}{Rds + R 10 + R 11} \times \\ ( Vdd - VGS 15 )\end{matrix} \qquad ( 5 )$$

The gate voltage of MN11 becomes VGS15 since no current is passing through R13. MN11 blocks with no output current flowing, because this time the gate voltage of MN12 is higher than that of MN11.

As for this operation, the changes in the gate voltages of MN11, MN12 are given by respective Expressions (6) and (7).

$$\begin{matrix}\frac{R 11}{Rds + R 10 + R 11} \times ( Vdd - VGS 15 ) & ( 6 ) \\ \frac{R 13}{Rds + R 12 + R 13} \times ( Vdd - VGS 15 ) & ( 7 )\end{matrix}$$

Each of these is clearly smaller than the power-supply voltage Vdd. That is, (Vdd−VGS15) is divided at the resistors R10, R11, R12, R13, and the output signal attenuated with respect to the input signal. If here R10, R11, R12, R13 are selected such that MN11, MN12 have sufficient voltage amplitude to allow switching, MN11, MN12 can be induced to switch without changing the gate voltages up to the extent of the power-supply voltage. Hence, the aforementioned influence of parasitic capacitances and channel charges below the gates can be abated.

The same also can be said about the control signals Up, UpB, the attenuator circuit 6a, and the differential switching circuit 2. Because the operation is the same except for reversed polarity, a detailed explanation is omitted. However, also in this case MN13, MN14 switch according to the signals Up, UpB, and the amplitudes of the gate voltages of MP11, MP12 are attenuated due to a division of the power-supply voltage at R14, R15, and R16, R17. Hence, error currents due to parasitic capacitances or channel charges that appear in the charge pump output can be reduced.

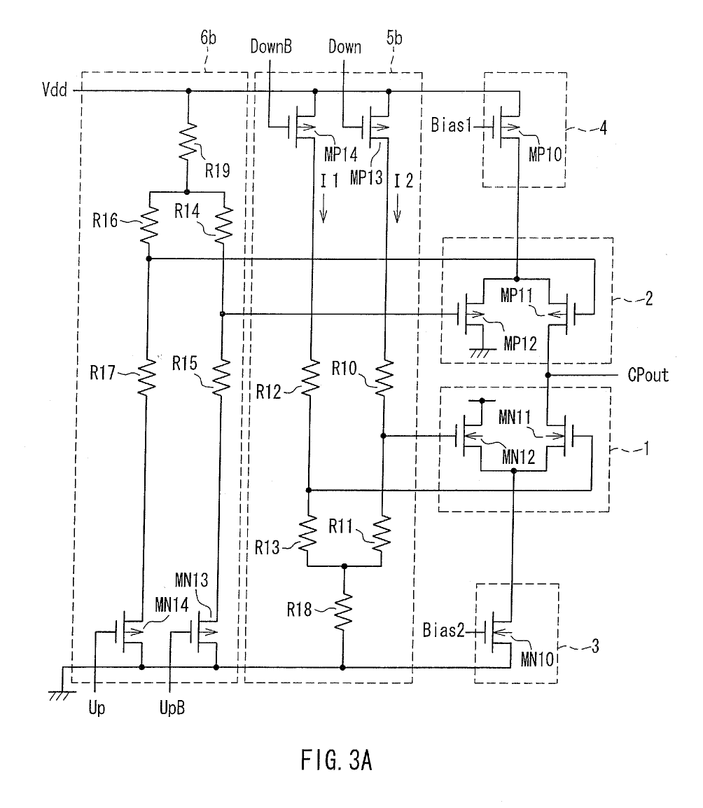

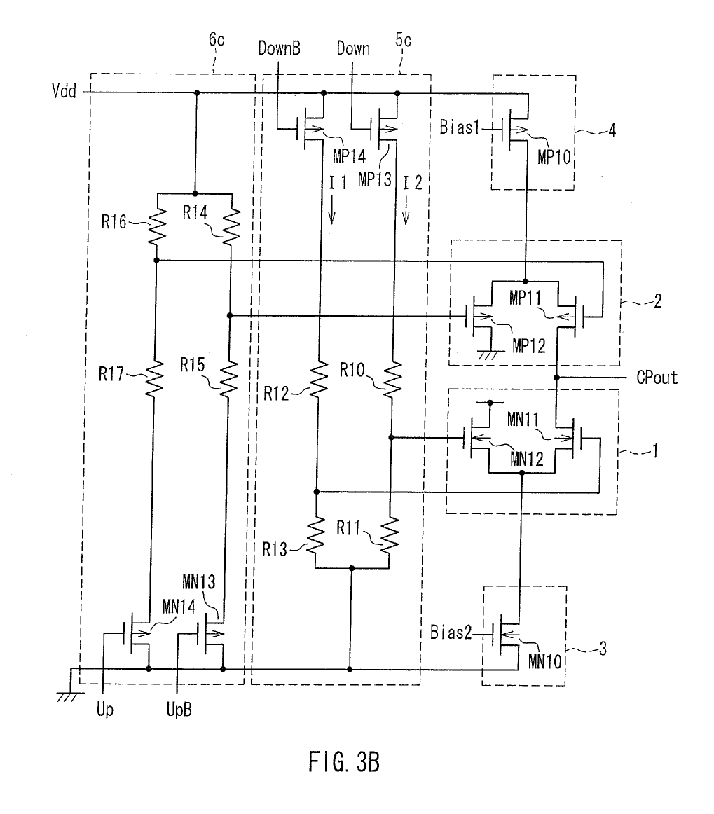

Furthermore, MN15 and MP15, which are included in the attenuator circuits 5a, 6a on FIG. 2, may be replaced by resistance elements R18, R19, as in attenuator circuits 5b, 6b shown in FIG. 3A. The same effect is also obtained when, as in attenuator circuits 5c, 6c shown in FIG. 3B, the node between R11 and R13 in FIG. 2 is grounded, and the node between R14 and R16 connected to the power-supply voltage Vdd.

### SECOND EMBODIMENT

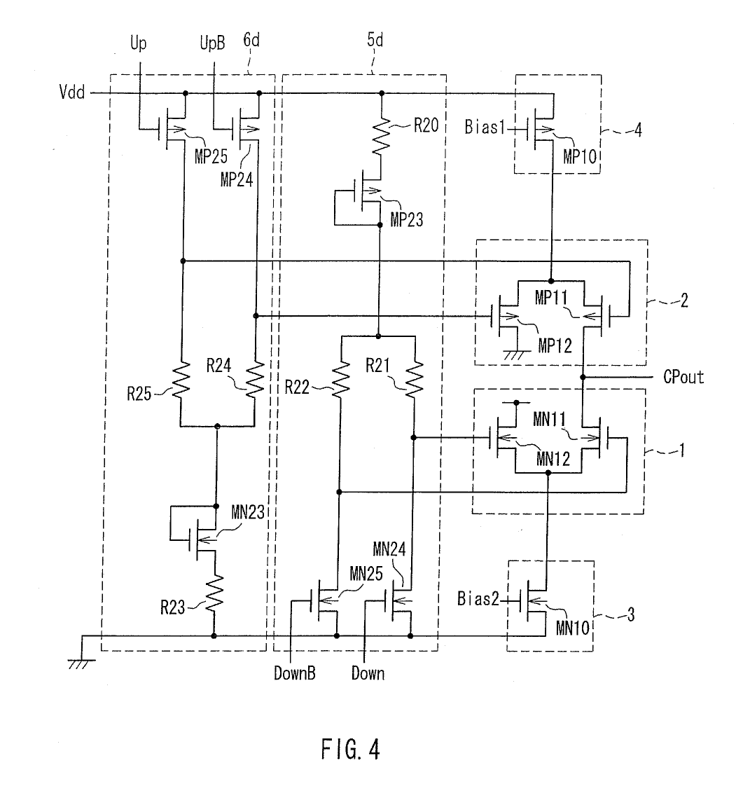

FIG. 4 shows a charge pump of a second embodiment. In the this charge pump, as in the first embodiment, the differential switching circuits 1, 2 respectively are composed of n-type MOS transistors MN11, MN12 and p-type MOS transistors MP11, MP12, the current sources 3, 4 being composed of n-type MOS transistor MN10, p-type MOS transistor MP10. These function as the electrical-current supply circuit of the charge pump.

An attenuator circuit 5d includes transistors MN24, MN25, MP23, resistance elements R20, R21, R22, and attenuates the signal level applied to the gates of MN11, MN12, which constitute the differential switching circuit 1.

In the same way, an attenuator circuit 6d includes transistors MP24, MP25, MN23, resistance elements R23, R24, R25, and attenuates the signal level applied to the gates of MP11, MP12, which constitute the differential switching circuit 2.

The switching operation on the side of the attenuator circuit 5d and the differential switching circuit 1 will be explained. First, when Down is high-level and DownB is low-level, MN24 is conductive while MN25 blocks. At this time, the gate voltage of MN12 assumes substantially ground voltage while the gate voltage of MN11 assumes a value given by Expression (8).

$$\frac{R 21}{Rds + R 21 + R 20} \times ( Vdd - VGS 23 ) \qquad ( 8 )$$

Here, VGS23 is the gate-to-source voltage of MP23 at on-time, and Rds the on-resistance of MN24. Since these values derive from a division of the power-supply voltage Vdd at the diode-connected transistor MP23 and the resistors R20, R21, it is lower than the power-supply voltage. That is, the input signals Down, DownB, while changing up to the extent of the power-supply voltage, are attenuated to a value that is lower in comparison. If this is configured to be a value higher than the threshold voltage Vth of the transistor, MN11 becomes conductive and causes current to flow at the output of the charge pump. Conversely, if Down, DownB are reversed, MN24 blocks, MN25 becomes conductive, the gate of MN11 assumes substantially ground voltage, so that the output current can be blocked. The gate voltage of MN12 assumes a value given by Expression (9), which is lower than the power-supply voltage.

$$\frac{R 22}{Rds + R 22 + R 20} \times ( Vdd - VGS 23 ) \qquad ( 9 )$$

Also in this case, the amplitudes of the gate voltages of MN11, MN12 are attenuated to less than the extent of the power-supply voltage, enabling inaccuracies of the output current due to channel charges and parasitic capacitances to be reduced.

For the attenuator circuit 6d in the same way, albeit with reversed polarity, the gate voltage of MP11 changes within a range between Vdd and a value given by Expression (10).

$$\frac{R 23 \times Vdd + ( Rds + R 24 ) \times VGS 23}{Rds + R 23 + R 24} \qquad ( 10 )$$

Also, the gate voltage of MP12 changes within a range between Vdd and a value given by Expression (11).

$$\frac{R 23 \times Vdd + ( Rds + R 25 ) \times VGS 23}{Rds + R 23 + R 25} \qquad ( 11 )$$

Here, Rds is the on-resistance of MP24, MP25, and VGS23 the gate-to-source voltage at on-time of MN23. Also in this case the voltage amplitude is attenuated to less than Vdd, enabling the aforementioned inaccuracies of the output current to be reduced.

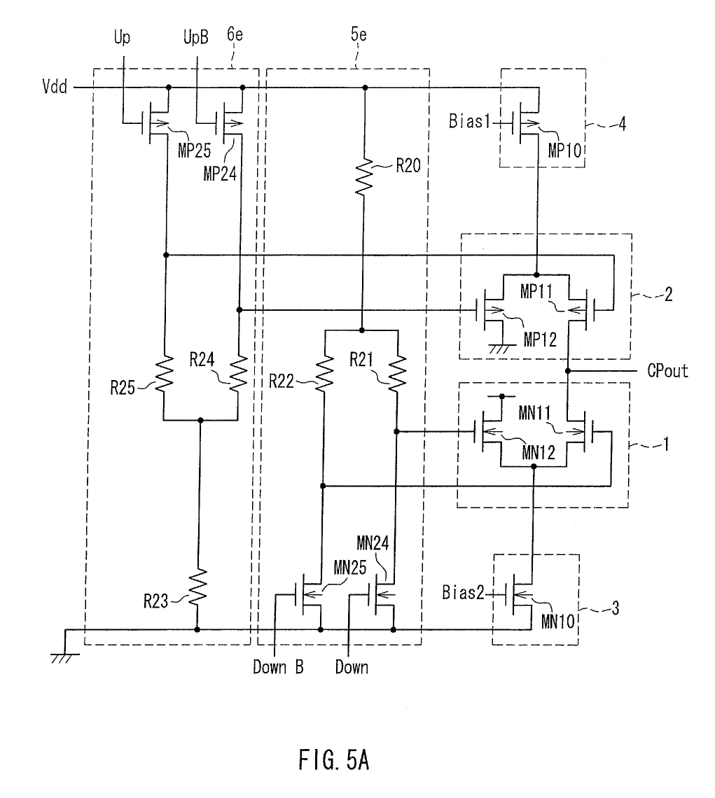

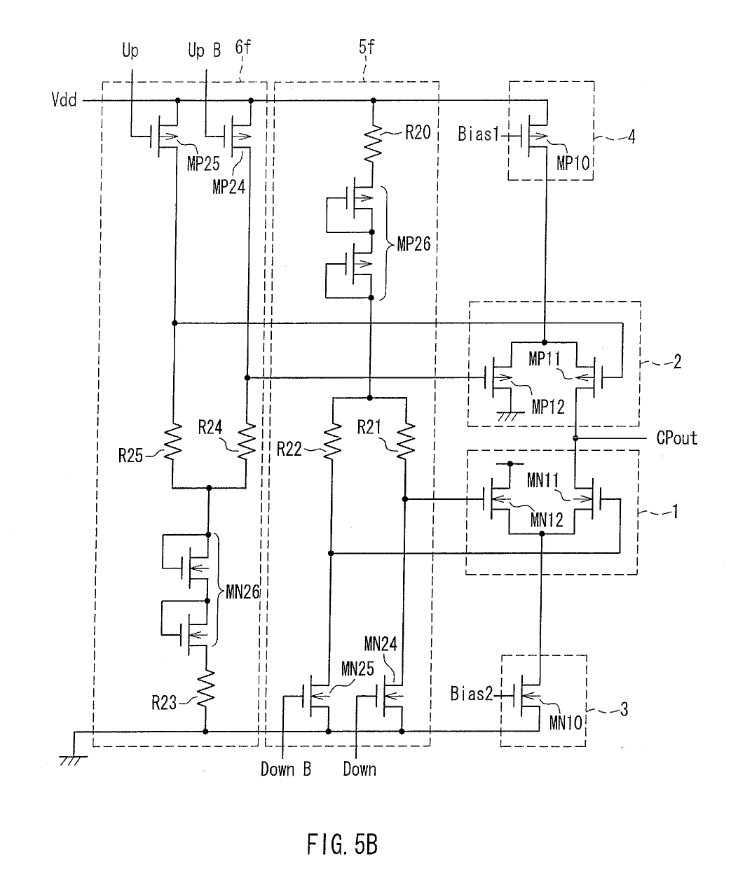

In the circuit of this embodiment, MP23, MN23 in FIG. 4 also may be omitted, in the way of attenuator circuits 5e, 6e shown in FIG. 5A. Also, a configuration is possible wherein, in the way of attenuator circuits 5f, 6f shown in FIG. 5B, diode-connected transistors MP26, MN26 corresponding to MP23, MN23 in FIG. 4 are connected multiply in series.

### THIRD EMBODIMENT

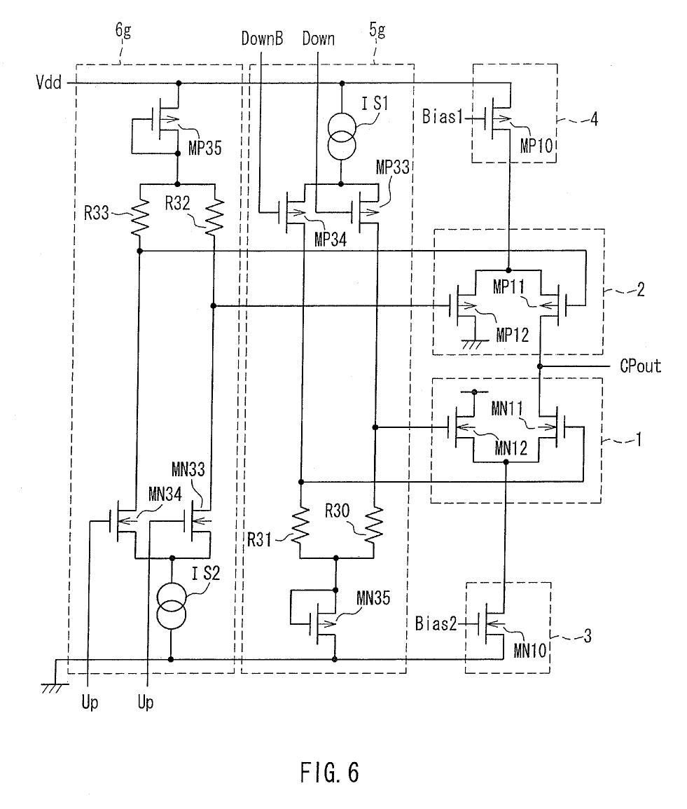

FIG. 6 shows a charge pump in a third embodiment. In this charge pump, in the same way as in the first embodiment, the differential switching circuits 1, 2 respectively are composed of the n-type MOS transistors MN11, MN12 and the p-type MOS transistors MP11, MP12, while the current sources 3, 4 are composed of the n-type MOS transistor MN10 and the p-type MOS transistor MP10. These function as the output electrical-current supply circuit of the charge pump.

An amplitude limiter circuit 5g including a current source IS1, transistors MP33, MP34, MN35, and resistance elements R30, R31 limits the amplitude of a control voltage applied to the gates of MN11, MN12, which constitute the differential switching circuit 1.

In the same way, an amplitude limiter circuit 6g including a current source IS2, transistors MN33, MN34, MP35, and resistance elements R32, R33 limits the amplitude of a control voltage applied to the gates of MP11, MP12, which constitute the differential switching circuit 2.

The operation of the amplitude limiter circuit 5g will be explained. When currently Down has become high-level, and DownB low-level, MP34 becomes conductive, while MP33 blocks. The gate voltage of MN11 assumes a value given by Expression (12), while the gate voltage of MN12 becomes VGS35.
IIS1·R31+VGS35 (12)

Here IIS1 is the electrical current of the current source IS1, and VGS35 the gate-to-source voltage at on-time of MN35.

When Down and DownB are reversed, the gate voltage of MN11 assumes VGS35, and the gate voltage of MN12 a value given by Expression (13).
IIS1·R30+VGS35 (13)

If values of R30, R31, and IIS1 are chosen appropriately, MN11, MN12 can be switched by a voltage amplitude lower than the extent of the power-supply voltage, enabling the aforementioned problems to be remedied.

The operation of the amplitude limiter circuit 6g is identical, the amplitude of the voltage applied to the gates of MP11, MP12 being either IIS2·R32 or IIS2·R33, depending on Up and UpB. If IIS2 and the values of R32, R33 are set appropriately, switching of MP11, MP12 by a voltage amplitude lower than the power-supply voltage is enabled, while at the same time inaccuracies in the output current that are caused by channel charges and parasitic capacitances can be reduced.

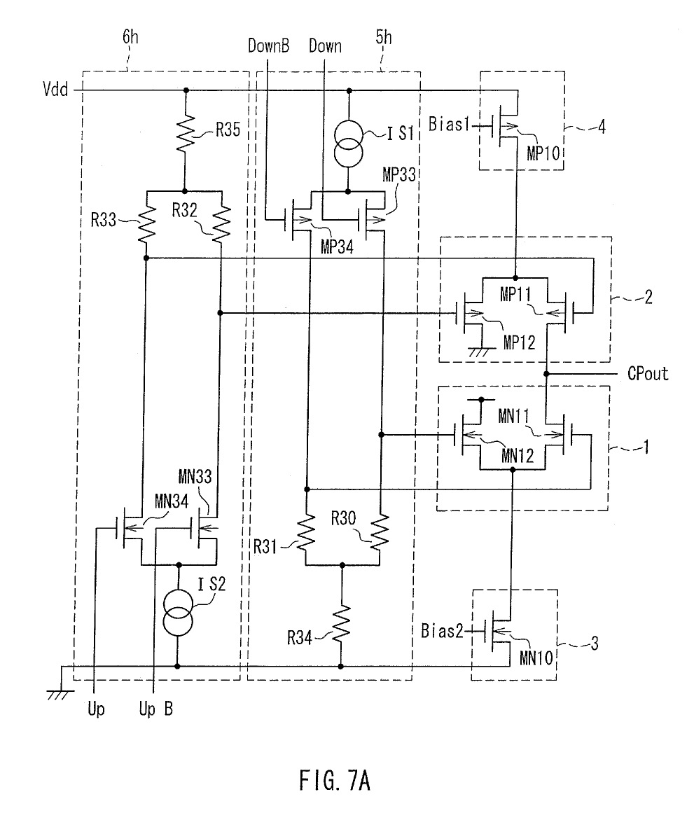

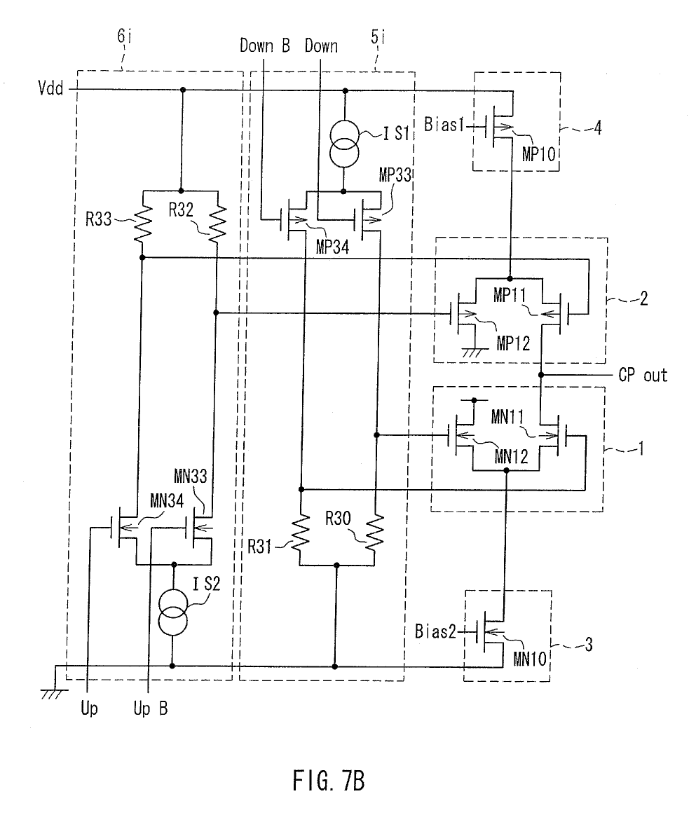

In the circuit of the present embodiment, resistance elements R34, R35 may be used as in amplitude limiter circuits 5h, 6h shown in FIG. 7A, instead of the diode-connected MN35, MP35 in FIG. 6. The same effect can also be obtained if, as in amplitude limiter circuits 5i, 6i shown in FIG. 7B, the node between the resistance elements R30, R31 in FIG. 6 is grounded, and the node between the resistance elements R33 and R32 is connected to the power-supply voltage, provided that the current sources IS1, IS2 and the values of the resistance elements R30, R31, R32, R33 are set to optimal values.

In the above embodiments, a great number of transistors for switching or capacitors for smoothing are not required. Thus, a large area is not required for integrated-circuit implementations, so that a low cost can be realized.

Furthermore, with the above three embodiments a voltage amplitude limiter or attenuator circuit also can be realized by an arbitrary combination of embodiments.

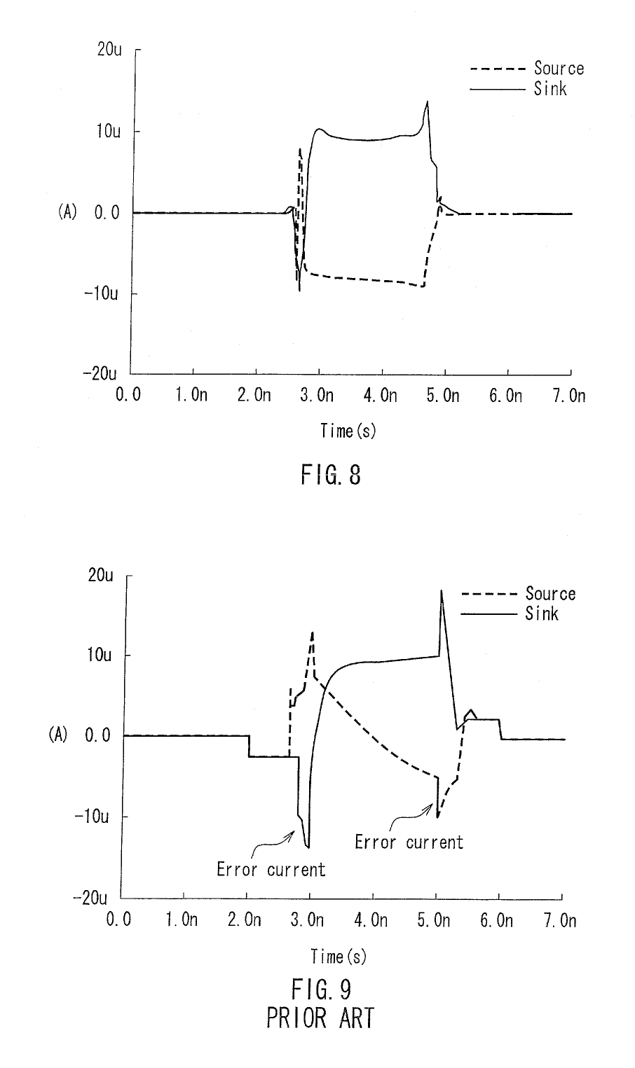

FIG. 8 shows a simulation result for the output current of the charge pump in the first embodiment shown in FIG. 2. Also, FIG. 9 shows a simulation result for the output current of a conventional charge pump shown in FIG. 11. The output current was set to about ±10 μA. In FIG. 8 and FIG. 9, “Source” stands for current supplied from output CPout, “Sink” for current sunken.

As shown in FIG. 9, in the case of the charge pump of FIG. 11, large error currents in spike shape arise in the output current, with no exact value being obtained for the current on the sourcing side. On the other hand, with the output waveform of FIG. 8 not only is the desired emission current obtained, but also the spike-shaped error currents are diminished, so that an output current faithful to the output of the phase comparator can be obtained.

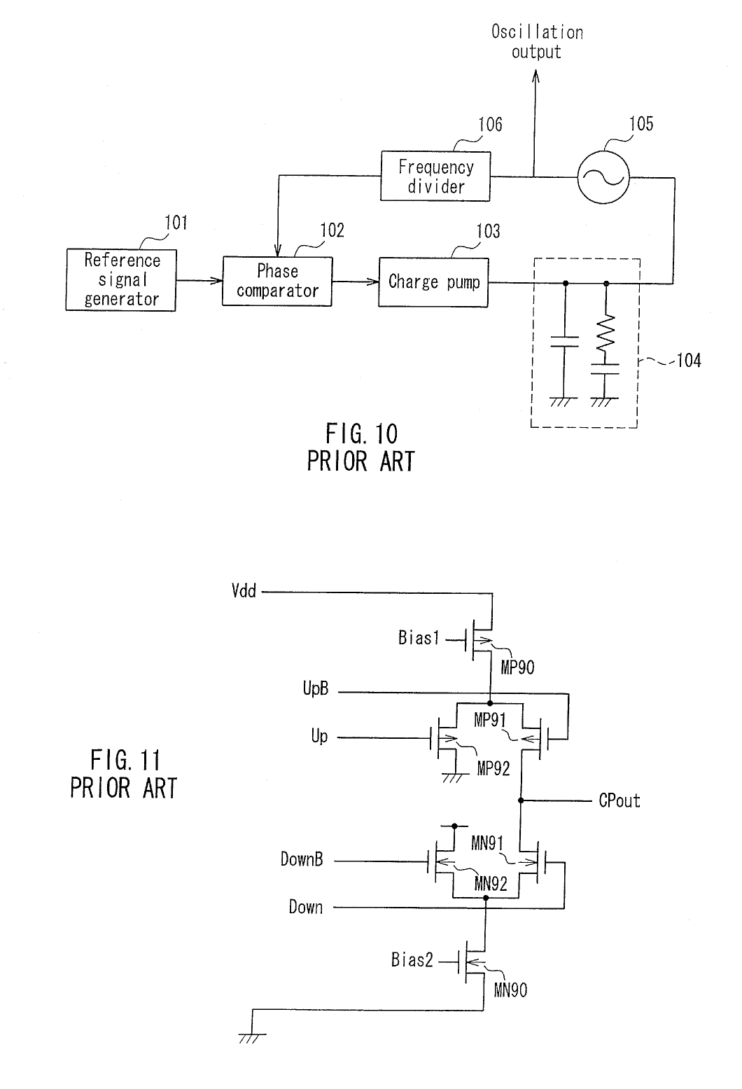

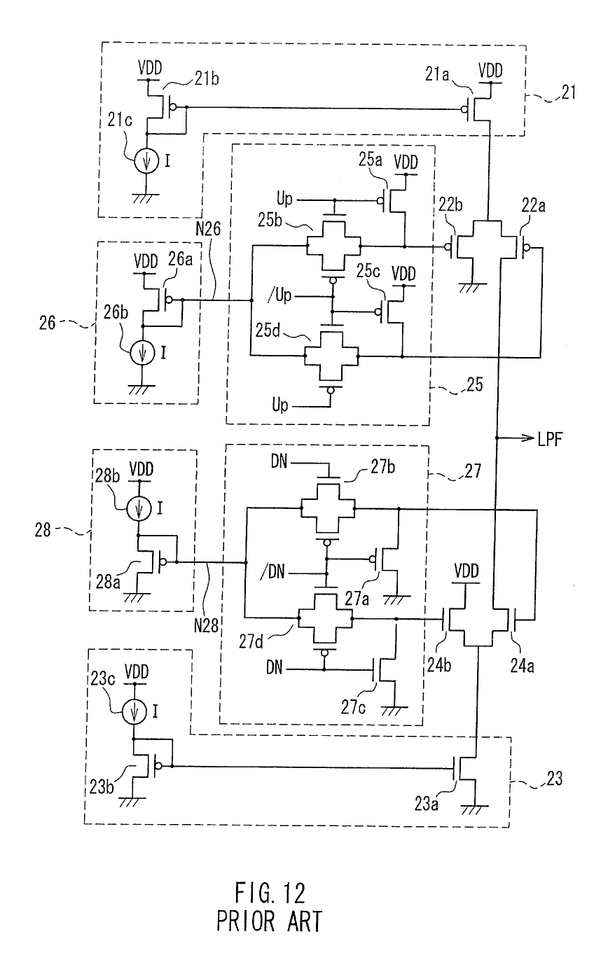

By using a charge pump having any one of the above configurations, the phase-locked loop circuit shown in FIG. 10 can be constructed.

The invention may be embodied in other forms without departing from the gist thereof The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A charge pump circuit comprising:
a first current source for sinking electrical current,
a first differential circuit for switching the electrical current of the first current source according to an input signal,
a second current source for sourcing electrical current,
a second differential circuit for switching the electrical current of the second current source according to an input signal, and
at least one amplitude limiter/attenuator circuit that reduces the input signal to a desired voltage amplitude and supplies it as a control signal that switches the first and second differential circuits,
wherein respective outputs of the first and second differential circuits are combined as output of the charge pump circuit.

2. The charge pump circuit according to claim 1, wherein
the amplitude limiter/attenuator circuit connected to the first differential circuit comprises:
a series circuit having a first switching element supplied with the input signal as control signal, a first resistance element, and a second resistance element, which are connected in series, the first switching element side being connected to a power-supply voltage and the second resistance element side being grounded; and
a series circuit having a second switching element supplied with the input signal as control signal, a third resistance element, and a fourth resistance element, which are connected in series, the second switching element side being connected to a power-supply voltage and the fourth resistance element side being grounded,
wherein output signals from the node between the first resistance element and the second resistance element and the node between the third resistance element and the fourth resistance element are inputted into the first differential circuit, and
the amplitude limiter/attenuator circuit connected to the second differential circuit comprises:
a series circuit having a third switching element supplied with the input signal as control signal, a fifth resistance element, and a sixth resistance element, which are connected in series, the third switching element side being connected to a ground potential and the sixth resistance element side being connected to the power-supply voltage; and
a series circuit having a fourth switching element supplied with the input signal as control signal, a seventh resistance element, and an eighth resistance element, which are connected in series, the fourth switching element side being connected to the ground potential and the eighth resistance element side being connected to the power-supply voltage,
wherein output signals from the node between the fifth resistance element and the sixth resistance element and the node between the seventh resistance element and the eighth resistance element are inputted into the second differential circuit.

3. The charge pump circuit according to claim 2, comprising:
a first diode-connected transistor inserted between the ground potential and the second resistance element together with the fourth resistance element, and
a second diode-connected transistor inserted between the power-supply voltage and the sixth resistance element together with the eighth resistance element.

4. The charge pump circuit according to claim 2, comprising:
a ninth resistance element inserted between the ground potential and the second resistance element together with the fourth resistance element, and
a tenth resistance element inserted between the power-supply voltage and the sixth resistance element together with the eighth resistance element.

5. The charge pump circuit according to claim 1, wherein
the amplitude limiter/attenuator circuit connected to the first differential circuit comprising:
an 11th resistance element connected at one end to a power-supply voltage;
a series circuit having a first switching element supplied with the input signal as control signal and a 12th resistance element, which are connected in series, the first switching element side being connected to a ground potential and the 12th resistance element side being connected to the other end of the 11th resistance element; and
a series circuit having a second switching element supplied with the input signal as control signal and a 13th resistance element, which are connected in series, the second switching element side being connected to the ground potential and the 13th resistance element side being connected to the other end of the 11th resistance element,
wherein output signals from the node between the first switching element and the 12th resistance element and the node between the second switching element and the 13th resistance element are inputted into the first differential circuit, and
the amplitude limiter/attenuator circuit connected to the second differential circuit comprising:
a 14th resistance element connected at one end to the ground potential;
a series circuit having a third switching element supplied with the input signal as control signal and a 15th resistance element, which are connected in series, the third switching element side being connected to the power-supply voltage and the 15th resistance element side being connected to the other end of the 14th resistance element; and
a series circuit having a fourth switching element supplied with the input signal as control signal and a 16th resistance element, which are connected in series, the fourth switching element side being connected to the power-supply voltage and the 16th resistance element side being connected to the other end of the 14th resistance element,
wherein output signals from the node between the third switching element and the 15th resistance element and the node between the fourth switching element and the 16th resistance element are inputted into the second differential circuit.

6. The charge pump circuit according to claim 5, comprising:
a third diode-connected transistor inserted between the 11th resistance element and the 12th resistance element together with the 13th resistance element, and
a fourth diode-connected transistor inserted between the 14th resistance element and the 15th resistance element together with the 16th resistance element.

7. The charge pump circuit according to claim 6, wherein:
the third transistor comprises a plurality of diode-connected transistors connected in series, and
the fourth transistor comprises a plurality of diode-connected transistors connected in series.

8. The charge pump circuit according to claim 1, wherein
the amplitude limiter/attenuator circuit connected to the first differential circuit comprising:
a third current source connected at one end to a power-supply voltage;
a series circuit having a first switching element supplied with the input signal as control signal and a 17th resistance element, which are connected in series, the first switching element side being connected to the other end of the third current source and the 17th resistance element side being grounded; and
a series circuit having a second switching element supplied with the input signal as control signal and an 18th resistance element, which are connected in series, the second switching element side being connected to the other end of the third current source and the 18th resistance element side being grounded,
wherein output signals from the node between the first switching element and the 17th resistance element and the node between the second switching element and the 18th resistance element are inputted into the first differential circuit, and
the amplitude limiter/attenuator circuit connected to the second differential circuit comprising:
a fourth current source grounded at one end;
a series circuit having a third switching element supplied with the input signal as control signal and a 19th resistance element, which are connected in series, the third switching element side being connected to the other end of the fourth current source and the 19th resistance element side being connected to the power-supply voltage; and
a series circuit having a fourth switching element supplied with the input signal as control signal and a 20th resistance element, which are connected in series, the fourth switching element side being connected to the other end of the fourth current source and the 20th resistance element side being connected to the power-supply voltage,
wherein output signals from the node between the third switching element and the 19th resistance element and the node between the fourth switching element and the 20th resistance element are inputted into the second differential circuit.

9. The charge pump circuit according to claim 8, comprising:
a fifth diode-connected transistor inserted between the ground potential and the 17th resistance element together with the 18th resistance element, and
a sixth diode-connected transistor inserted between the power-supply voltage and the 19th resistance element together with the 20th resistance element.

10. The charge pump circuit according to claim 8, comprising:
a 21st resistance element inserted between the ground potential and the 17th resistance element together with the 18th resistance element, and
a 22nd resistance element inserted between the power-supply voltage and the 19th resistance element together with the 20th resistance element.

11. A phase-locked loop circuit, comprising:
a voltage-controlled oscillator,
a frequency divider that divides a frequency of an output signal of the voltage-controlled oscillator,
a phase comparator that compares the phases of a reference signal and an output signal of the frequency divider,
a charge pump controlled by an output signal of the phase comparator, and
a low-pass filter supplied with the output of the charge pump,
the voltage-controlled oscillator being controlled by the output of the low-pass filter,
wherein for the charge-pump circuit, a charge pump circuit according to claim 1 is used, and
the output signal of the phase comparator is inputted as an input signal into the amplitude limiter/attenuator circuit.

12. A reception device using the phase-locked loop circuit according to claim 11.

13. A transmission device using the phase-locked loop circuit according to claim 11.
